(19) United States
(12) Patent Application Publication
(10) Pub. No.: US 2024/0260411 A1
(43) Pub. Date: Aug. 1, 2024

(54) Light Emitting Substrate, Display Panel and Display Apparatus

(71) Applicant: BOE Technology Group Co., Ltd., Beijing (CN)

(72) Inventors: Zhihui ZHANG, Beijing (CN); Bei WANG, Beijing (CN); Hao GAO, Beijing (CN); Yan FAN, Beijing (CN); Xiangmin WEN, Beijing (CN)

(21) Appl. No.: 18/020,420

(22) PCT Filed: Jun. 21, 2022
(86) PCT No.: PCT/CN2022/100167

§ 371 Date: Feb. 8, 2023

(51) Int. Cl. H10K 59/80; H10K 50/13; H10K 59/35

(52) U.S. Cl. CPC H10K 59/875; H10K 50/13; H10K 59/35

(57) ABSTRACT

A light emitting substrate includes: a first base substrate, a plurality of light emitting devices located on the first base substrate, wherein the light emitting devices include a first light emitting device, a second light emitting device and a third light emitting device, each of the light emitting devices includes a first electrode layer, a light emitting functional layer and a second electrode layer which are stacked, the light emitting functional layer includes an emitting layer including a first emitting layer in the first light emitting device, a second emitting layer in the second light emitting device and a third emitting layer in the third light emitting device; the material of the first emitting layer is different from the material of the second emitting layer, and the material of the first emitting layer is different from the material of the third emitting layer.

### CROSS-REFERENCE TO RELATED APPLICATION

This application is a national stage application of PCT Application No. PCT/CN2022/100167, which is filed on Jun. 21, 2022 and entitled “Light Emitting Substrate, Display Panel and Display Apparatus”, the content of which should be regarded as being incorporated herein by reference.

### TECHNICAL FIELD

Embodiments of the present disclosure relate to, but are not limited to, the field of display technologies, and in particular, relate to a light emitting substrate, a display panel and a display apparatus.

### BACKGROUND

Quantum Dot (QD), particle size of which is generally nanometer (2 nm to 10 nm), is formed by combining core and shell and wrapping it with polymer coating. Since the size of quantum dot is in the range of Bohr radius, it can present obvious quantum confinement effect, so quantum dot can emit light with different colors and wavelengths along with a narrow emission spectra (for example, 15 nm to 30 nm), thus having high color purity and good color gamut level.

Quantum Dots-Organic Light Emitting Diodes (QD-OLED) is a new display device which uses OLED as excitation light source and QD as color conversion layer to realize full-color display. QD-OLED devices show a good application prospect, which can present good color purity and color gamut level. QD can be formed by inorganic materials through printing process, which reduces the waste of materials to a certain extent. Moreover, the properties of inorganic materials have better stability and water and oxygen resistance, presenting high commercial value and display level.

### SUMMARY

The following is a summary of subject matters described herein in detail. The summary is not intended to limit the protection scope of the disclosure.

An embodiment of the present disclosure provides a light emitting substrate, which includes:
a first base substrate;
a plurality of light emitting devices on the first base substrate, the light emitting devices include a first light emitting device, a second light emitting device and a third light emitting device, each of the light emitting devices includes a first electrode layer, a light emitting functional layer and a second electrode layer which are stacked, the light emitting functional layer includes a emitting layer, the emitting layer includes a first emitting layer in the first light emitting device, a second emitting layer in the second light emitting device and a third emitting layer in the third light emitting device;
wherein a material of the first emitting layer is different from a material of the second emitting layer, and a material of the first emitting layer is different from a material of the third emitting layer.

Embodiments of the present disclosure also provide a display panel having a plurality of repeated pixel units, at least one pixel unit includes a first sub-pixel, a second sub-pixel and a third sub-pixel displaying different colors, wherein the display panel includes the light emitting substrate provided in the above embodiment of the present disclosure, a thin film encapsulation layer, a color conversion layer, and a color filter layer; wherein,
the first light emitting device of the light emitting substrate is located in the first sub-pixel, the second light emitting device of the light emitting substrate is located in the second sub-pixel, and the third light emitting device of the light emitting substrate is located in the third sub-pixel;
the thin film encapsulation layer is disposed at a side of the light emitting substrate away from the first base substrate;
the color conversion layer is disposed at a side of the thin film encapsulation layer away from the first base substrate, the color conversion layer includes a transmission pattern, a first color conversion pattern and a second color conversion pattern, wherein the transmission pattern is located in the first sub-pixel, the first color conversion pattern is located in the second sub-pixel, and the second color conversion pattern is located in the third sub-pixel;
the color filter layer is positioned at a side of the color conversion layer away from the first base substrate and at least includes a first light shielding pattern, a first color filter pattern and a second color filter pattern, wherein the first light shielding pattern defines a plurality of light transmitting areas, wherein the light transmitting areas include a first light transmitting area corresponding to the first sub-pixel, a second light transmitting area corresponding to the second sub-pixel and a third light transmitting area corresponding to the third sub-pixel.

An embodiment of the present disclosure further provides a display apparatus, which includes the display panel according to the embodiments of the present disclosure described above, a drive integrated circuit and a power supply circuit.

Other aspects may be understood upon reading and understanding the drawings and detailed description.

### BRIEF DESCRIPTION OF DRAWINGS

The accompanying drawings are used for providing understanding of technical solutions of the present disclosure, and form a part of the specification. They are used for explaining the technical solutions of the present disclosure together with the embodiments of the present disclosure, but do not form a limitation on the technical solutions of the present disclosure.

FIG. 1 is a schematic diagram of a structure of a common quantum dot-organic light emitting diode at present;

FIG. 2 is a schematic diagram of a structure of a light emitting substrate according to an exemplary embodiment of the present disclosure.

FIG. 3 is a schematic diagram of a structure of a light emitting substrate according to another exemplary embodiment of the present disclosure.

FIG. 4 is a spectrogram of an electroluminescence spectrum and an absorption spectrum of a first emitting layer of a light emitting substrate under different backlight viewing angles according to an exemplary embodiment of the present disclosure;

FIG. 5 is a spectrogram of an electroluminescence spectrum and an absorption spectrum of a second emitting layer of the light emitting substrate shown in FIG. 4 under different backlight viewing angles;

FIG. 6 is a spectrogram of a photoluminescence spectrum of a first emitting layer and a second emitting layer of a light emitting substrate according to an exemplary embodiment of the present disclosure;

FIG. 7 is a schematic diagram of a structure of a light emitting substrate according to yet another embodiment of the present disclosure.

FIG. 8 is a schematic diagram of a structure of a light emitting substrate according to yet another exemplary embodiment of the present disclosure.

FIG. 9 is a schematic diagram of a structure of a display panel according to an exemplary embodiment of the present disclosure.

FIG. 10 is a spectrogram of electroluminescence spectrum and absorption spectrum of device structure 1 and device structure 3 at a backlight viewing angle of 0°;

FIG. 11 is a spectrogram of electroluminescence spectrum and absorption spectrum of device structure 1 and device structure 3 at a backlight viewing angle of 50°.

Meanings of reference signs in the accompanying drawings are as follows.

10—first base substrate; 20—first electrode layer; 30—hole transport layer; 31—first hole transport layer; 311—first sub-layer of first hole transport layer; 312—second sub-layer of first hole transport layer; 32—second hole transport layer; 321—first sub-layer of second hole transport layer; 322—second sub-layer of second hole transport layer; 33—third hole transport layer; 331—first sub-layer of third hole transport layer; 332—second sub-layer of third hole transport layer; 34—first sub-hole transport layer; 35—second sub-hole transport layer; 40—emitting layer; 41—first emitting layer; 42—second emitting layer; 43—third emitting layer; 50—second electrode layer; 60—pixel definition layer; 70—thin film encapsulation layer; 80—light blocking layer; 90—quantum dot conversion layer; 100—transparent emitting layer; 110—posterior film layer; 120—color conversion layer; 121—transmission pattern; 122—first color conversion pattern; 123—second color conversion pattern; 124—bank; 130—color filter layer; 131—first light shielding pattern; 132—first color filter pattern; 133—second color filter pattern; 134—black matrix; 140—filling layer; 150—insulation layer; 160—first capping layer; 170—second capping layer; 180—second base substrate; LD1—first light emitting device; LD2—second light emitting device; LD3—third light emitting device; TA1—first light transmitting area; TA2—second light transmitting area; TA3—third light transmitting area; T1—first switch element; T2—second switch element; T3—third switch element; LA1—first light emitting area; LA2—second light emitting area; LA3—third light emitting area; NLA—non-light emitting area.

### DETAILED DESCRIPTION

Implementations herein may be implemented in multiple different forms. Those of ordinary skills in the art can readily appreciate a fact that the implementations and contents may be varied into various forms without departing from the spirit and scope of the present disclosure. Therefore, the present disclosure should not be explained as being limited to contents described in following implementations only. The embodiments in the present disclosure and features in the embodiments may be combined randomly with each other without conflict.

Scales of the drawings in the present disclosure may be used as a reference in the actual process, but are not limited thereto. For example, the width-length ratio of the channel, the thickness and spacing of each film layer, and the width and spacing of each signal line may be adjusted according to actual needs. The number of pixels in the display substrate and the number of sub-pixels in each pixel are not limited to the numbers shown in the drawings. The drawings described in the present disclosure are schematic structure diagrams only, and one implementation of the present disclosure is not limited to the shapes, numerical values or the like shown in the drawings.

In the description of the present disclosure, ordinal numerals such as “first”, “second” and “third” are set to avoid confusion of constituents, but not intended for restriction in quantity.

In the specification, for convenience, wordings indicating orientation or positional relationships, such as “middle”, “upper”, “lower”, “front”, “back”, “vertical”, “horizontal”, “top”, “bottom”, “inside”, and “outside”, are used for illustrating positional relationships between constituent elements with reference to the drawings, and are merely for facilitating the description of the specification and simplifying the description, rather than indicating or implying that a referred apparatus or element must have a particular orientation and be constructed and operated in the particular orientation. Therefore, they cannot be understood as limitations on the present disclosure. The positional relationships between the constituent elements may be changed as appropriate according to directions for describing the various constituent elements. Therefore, appropriate replacements may be made according to situations without being limited to the wordings described in the specification.

In the specification, unless otherwise specified and defined explicitly, terms “disposed” and “connect” should be understood in a broad sense. It may be a mechanical connection or an electrical connection. It may be a direct mutual connection, or an indirect connection through middleware, or internal communication between two components. Those of ordinary skill in the art may understand specific meanings of these terms in the present disclosure according to specific situations.

In the specification, a “film” and a “layer” are interchangeable. For example, an “emitting layer” may be replaced with an “emitting film” sometimes.

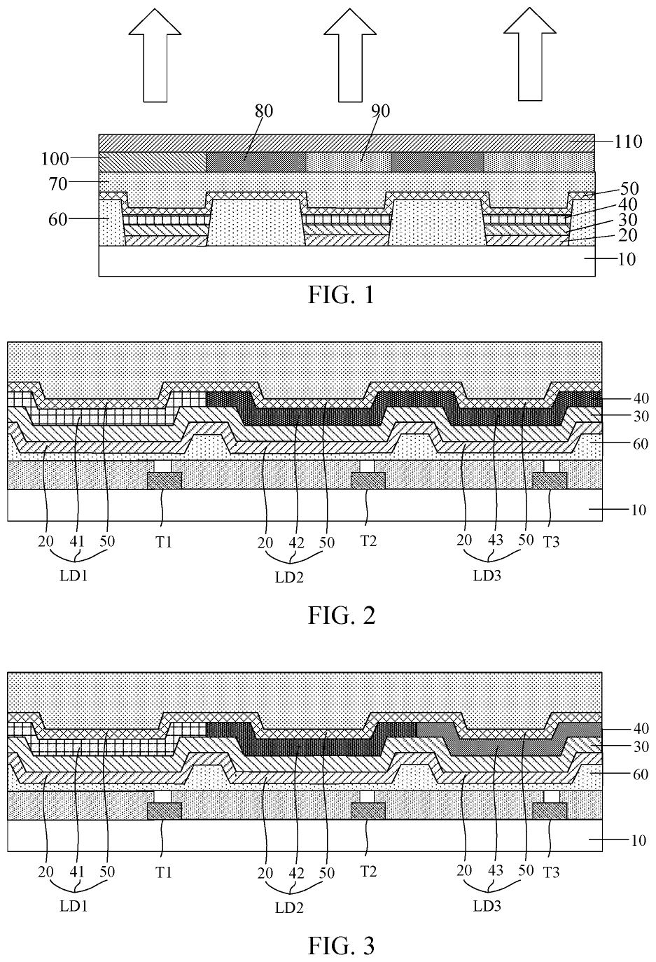

FIG. 1 is a schematic diagram of a structure of a common quantum dot-organic light emitting diode at present. As shown in FIG. 1, a common quantum dot-organic light emitting diode at present includes a first base substrate 10, a first electrode layer 20, a hole transport layer 30 (HTL), a emitting layer 40 (EML), a second electrode layer 50, a pixel definition layer 60 (PDL), a thin film encapsulation layer 70, a light blocking layer 80, a quantum dot conversion layer 90, a transparent emitting layer 100 and a posterior film layer 110 (including a second base substrate, etc.). The first electrode layer 20 is disposed at a side of the first base substrate 10, the hole transport layer 30 is disposed at a side of the first electrode layer 20 away from the first base substrate 10, the emitting layer 40 is disposed at a side of the hole transport layer 30 away from the first base substrate 10, the second electrode layer 50 is disposed at a side of the emitting layer 40 away from the first base substrate 10, the pixel definition layer 60 spaces the first electrode layer 20, the hole transport layer 30, the emitting layer 40 and the second electrode layer 50 of the different sub-pixels, the thin film encapsulation layer 70 is disposed at a side of the second electrode layer 50 away from the first base substrate 10, the light blocking layer 80, the quantum dot conversion layer 90 and the transparent emitting layer 100 are disposed at a side of the thin film encapsulation layer 70 away from the first base substrate 10, and the transparent emitting layer 100 is located in a blue sub-pixel area, the quantum dot conversion layer 90 is located in a red sub-pixel area and a green sub-pixel area and includes a red quantum dot conversion pattern and a green quantum dot conversion pattern, the light blocking layer 80 is disposed between the transparent emitting layer 100 and the quantum dot conversion layer 90 and between the red quantum dot conversion pattern and the green quantum dot conversion pattern, and a posterior film layer 110 is disposed at a side of the light blocking layer 80, the quantum dot conversion layer 90 and the transparent emitting layer 100 away from the first base substrate 10; wherein, the emitting layers 40 of different sub-pixels are formed of the same material.

The blue light emitted by the emitting layer corresponding to the blue sub-pixel area of the quantum dot-organic light emitting diode device can be directly emitted, and the blue light emitted by the emitting layer corresponding to the red sub-pixel area and the green sub-pixel area is absorbed by the quantum dots of the red quantum dot conversion pattern and the green quantum dot conversion pattern and converted into red light and green light for emitting. Therefore, the absorption and conversion efficiency of quantum dots of the red quantum dot conversion pattern and green quantum dot conversion pattern have great influence on the device performance. With the increase of the viewing angle of the blue light emitted by the emitting layer, it is easy for quantum dots to absorb insufficient light energy from large viewing angle, which leads to the decrease of light emission efficiency in red sub-pixel area and green sub-pixel area, and then leads to the decrease efficiency and color gamut level of the device.

An embodiment of the present disclosure provides a light emitting substrate, which includes:
a first base substrate;
a plurality of light emitting devices on the first base substrate, the light emitting devices include a first light emitting device, a second light emitting device and a third light emitting device, each of the light emitting devices includes a first electrode layer, a light emitting functional layer and a second electrode layer which are stacked, the light emitting functional layer includes a emitting layer, the emitting layer includes a first emitting layer in the first light emitting device, a second emitting layer in the second light emitting device and a third emitting layer in the third light emitting device;
wherein the material of the first emitting layer is different from that of the second emitting layer, and the material of the first emitting layer is different from that of the third emitting layer.

According to the following formula, the performance of quantum dot-OLED devices is obviously affected by the intrinsic spectral microcavity effect of light emitting material:

$$EL = MC \times PL ;$$

where, EL is an electroluminescent spectroscopy; MC is the enhanced spectrum of microcavity, which is affected by a microcavity gain factor (Gcav); PL is a photoluminescence spectroscopy;
the calculation formula of the microcavity gain factor (Gcav) is as following:

$${G}_{cav} ( λ ) = [ 1 - \frac{4 \sqrt{R 1} sin ( \frac{φ 1 - 2 KL 1}{2} )}{{( 1 + \sqrt{R 1} )}^{2}} ] \times [ \frac{T 2 {( 1 + \sqrt{R 1} )}^{2}}{\begin{matrix}{( 1 - \sqrt{R 1 R 2} )}^{2} + \\ 4 \sqrt{R 1 R 2 sin 2 ( \frac{φ 1 + φ 2 - 2 KL}{2} )}\end{matrix}} ] \times \frac{{τ}_{cav}}{{τ}_{o}}$$

where K is the wave vector; λ is the wavelength; R1 is the reflectivity of the anode; L1 is the optical length from the luminescence center to the anode; L is the total cavity length of the device; R2 is the reflectivity of the cathode; T2 is the transmittance at the cathode side; τ₀ is the lifetime of excited state in free space, τ_{cav} is the lifetime of excited state in microcavity.

When the film structure of the device is fixed, the shape of the microcavity enhancement spectrum MC is basically unchanged, so the EL and PL of the final emitted light are closely related, so the definition relationship of PL can be determined by analyzing the change relationship of EL.

The first emitting layer of the light emitting substrate provided by the embodiment of the present disclosure is formed of a light emitting material different from that of both the second emitting layer and the third emitting layer, the electroluminescence spectra of the first emitting layer of the blue sub-pixel area and the second emitting layer and the third emitting layer of the red sub-pixel area and the green sub-pixel area can be different, so that the electroluminescence spectra and the photoluminescence spectra of the emitting layers can be adjusted by selecting suitable light emitting materials. When the light emitting substrate provided by the embodiment of the present disclosure is adopted as the backlight of the QD-OLED device, it can not only ensure the efficiency and color gamut level of the blue sub-pixel area, but also improve the light absorption and light emission of quantum dots in the red sub-pixel area and the green sub-pixel area, thus further improving the overall efficiency and color gamut level of the device and reducing the power consumption of the display device.

FIG. 2 is a schematic diagram of a structure of a light emitting substrate according to an exemplary embodiment of the present disclosure; FIG. 3 is a schematic diagram of a structure of a light emitting substrate according to another exemplary embodiment of the present disclosure. As shown in FIG. 2 and FIG. 3, the light emitting substrate includes: a first base substrate 10 and a plurality of light emitting devices on the first base substrate 10. The light emitting devices include: a first light emitting device LD1, a second light emitting device LD2 and a third light emitting device LD3. The light emitting device includes a first electrode layer 20, a light emitting functional layer, a second electrode layer 50 and a pixel definition layer 60, the light emitting functional layer includes an emitting layer 40, the emitting layer 40 includes a first emitting layer 41 located in the first light emitting device LD1, a second emitting layer 42 located in the second light emitting device LD2 and a third emitting layer 43 located in the third light emitting device LD3;
the material of the first emitting layer 41 is different from the material of the second emitting layer 42 and the material of the first emitting layer 41 is different from the material of the third emitting layer 43.

In an exemplary embodiment of the present disclosure, the material of the second emitting layer and the material of the third emitting layer may be the same or different. In the light emitting substrate shown in FIG. 2, the material of the second emitting layer 42 is the same as that of the third emitting layer 43, and in the light emitting substrate shown in FIG. 3, the material of the second emitting layer 42 is different from that of the third emitting layer 43.

In an exemplary embodiment of the present disclosure, the second emitting layer 42 and the third emitting layer 43 may be formed of one continuous film layer as shown in FIG. 2, or the second emitting layer 42 and the third emitting layer 43 may be respectively formed of two film layers as shown in FIG. 3.

In an exemplary embodiment of the present disclosure, a photoluminescence spectrum of the first emitting layer may include a first main peak and a first shoulder peak, a photoluminescence spectrum of the second emitting layer may include a second main peak and a second shoulder peak, and a photoluminescence spectrum of the third emitting layer may include a third main peak and a third shoulder peak.

In an exemplary embodiment of the present disclosure, a Full Width At Half-Maximum (FWHM) of the photoluminescence spectrum of the first emitting layer may be narrower than that of the photoluminescence spectrum of the second emitting layer, and a FWHM of the photoluminescence spectrum of the first emitting layer may be narrower than that of the photoluminescence spectrum of the third emitting layer.

In an exemplary embodiment of the present disclosure, the ratio of the FWHM of the photoluminescence spectrum of the first emitting layer to the FWHM of the photoluminescence spectrum of the second emitting layer may be 0.6:1 to 0.85:1. The ratio of the FWHM of the photoluminescence spectrum of the first emitting layer to the FWHM of the photoluminescence spectrum of the third emitting layer can be 0.6:1 to 0.85:1. For example, the ratio of the FWHM of the photoluminescence spectrum of the first emitting layer to the FWHM of the photoluminescence spectrum of the second emitting layer may be 0.6:1, 0.65:1, 0.7:1, 0.75:1, 0.8:1, 0.85:1, the ratio of the FWHM of the photoluminescence spectrum of the first emitting layer to the FWHM of the photoluminescence spectrum of the third emitting layer can be 0.6:1, 0.65:1, 0.7:1, 0.75:1, 0.8:1, 0.85:1.

When the ratio of the FWHM of the photoluminescence spectrum of the first emitting layer to the FWHM of the photoluminescence spectrum of the second emitting layer is about 0.6:1 to 0.85:1, the ratio of the FWHM of the photoluminescence spectrum of the first emitting layer to the FWHM of the photoluminescence spectrum of the third emitting layer is about 0.6:1 to 0.85:1, it is beneficial to ensuring the efficiency and color gamut level of the blue sub-pixel area, and improving the light absorption and light emission of quantum dots in the red sub-pixel area and the green sub-pixel area, thus further improving the overall efficiency and color gamut level of the display device and reducing the power consumption of the display device.

In an exemplary embodiment of the present disclosure, the FWHM of the photoluminescence spectrum of the first emitting layer may be 20±2 nm, the FWHM of the photoluminescence spectrum of the second emitting layer may be 28±2 nm, and the FWHM of the photoluminescence spectrum of the third emitting layer may be 28±2 nm.

In an exemplary embodiment of the present disclosure, a ratio of a proportion of an area of the first shoulder peak in the photoluminescence spectrum of the first emitting layer to a proportion of an area of the second shoulder peak in the photoluminescence spectrum of the second emitting layer may be 0.5:1 to 0.9:1, a ratio of the proportion of the area of the first shoulder peak in the photoluminescence spectrum of the first emitting layer to a proportion of an area of the third shoulder peak in the photoluminescence spectrum of the third emitting layer may be 0.5:1 to 0.9:1.

For example, the ratio of the proportion of the area of the first shoulder peak in the photoluminescence spectrum of the first emitting layer to the proportion of the area of the second shoulder peak in the photoluminescence spectrum of the second emitting layer may be 0.5:1, 0.55:1, 0.6:1, 0.65:1, 0.7:1, 0.75:1, 0.8:1, 0.85:1, 0.9:1, the ratio of the proportion of the area of the first shoulder peak in the photoluminescence spectrum of the first emitting layer to the proportion of the area of the third shoulder peak in the photoluminescence spectrum of the third emitting layer may be 0.5:1, 0.55:1, 0.6:1, 0.65:1, 0.7:1, 0.75:1, 0.8:1, 0.85:1, 0.9:1.

When the ratio of the proportion of the area of the first shoulder peak in the photoluminescence spectrum area of the first emitting layer to the proportion of the area of the second shoulder peak in the photoluminescence spectrum of the second emitting layer are about 0.5:1 to 0.9:1, the ratio of the proportion of the area of the first shoulder peak in the photoluminescence spectrum area of the first emitting layer to the proportion of the area of the third shoulder peak in the photoluminescence spectrum of the third emitting layer is about 0.5:1 to 0.9:1, it is beneficial to ensuring the efficiency and color gamut level of the blue sub-pixel area, and improving the light absorption and light emission of quantum dots in the red sub-pixel area and the green sub-pixel area, thus further improving the overall efficiency and color gamut level of the display device and reducing the power consumption of the display device.

In an exemplary embodiment of the present disclosure, the area of the first shoulder peak may account for 23%±4% of the area of the photoluminescence spectrum of the first emitting layer, the area of the second shoulder peak may account for 34%±4% of the area of the photoluminescence spectrum of the second emitting layer, and the area of the third shoulder peak may account for 34%±4% of the area of the photoluminescence spectrum of the third emitting layer.

In an exemplary embodiment of the present disclosure, a difference between the peak wavelength of the first shoulder peak and the peak wavelength of the second shoulder peak may be 5 nm to 25 nm, and a difference between the peak wavelength of the first shoulder peak and the peak wavelength of the third shoulder peak may be 5 nm to 25 nm.

When the difference between the peak wavelength of the first shoulder peak and the peak wavelength of the second shoulder peak is about 5 nm to 25 nm, the difference between the peak wavelength of the first shoulder peak and the peak wavelength of the third shoulder peak is about 5 nm to 25 nm, it is beneficial to ensuring the efficiency and color gamut level of the blue sub-pixel area, and improving the light absorption and light emission of quantum dots in the red sub-pixel area and the green sub-pixel area, thus further improving the overall efficiency and color gamut level of the display device and reducing the power consumption of the display device.

In an exemplary embodiment of the present disclosure, the peak wavelength of the first shoulder peak may be 5 nm to 25 nm less than the peak wavelength of the second shoulder peak, and the peak wavelength of the first shoulder peak may be 5 nm to 25 nm less than the peak wavelength of the third shoulder peak. For example, the peak wavelength of the first shoulder peak may be 5 nm, 10 nm, 15 nm, 20 nm, 25 nm less than the peak wavelength of the second shoulder peak, and the peak wavelength of the first shoulder peak may be 5 nm, 10 nm, 15 nm, 20 nm, 25 nm less than the peak wavelength of the third shoulder peak.

In an exemplary embodiment of the present disclosure, the first shoulder peak may have a peak wavelength of 490±5 nm, the second shoulder peak may have a peak wavelength of 505±5 nm, and the third shoulder peak may have a peak wavelength of 505±5 nm.

In an exemplary embodiment of the present disclosure, the material of the first emitting layer, the material of the second emitting layer, and the material of the third emitting layer may each independently include any one or more of oxadiazole and its derivative light emitting materials, triazole and its derivative light emitting materials, rhodamine and its derivative light emitting materials, 1,8-naphthalimide and its derivative light emitting materials, pyrazoline and its derivative light emitting materials, triphenylamine and its derivative light emitting materials, porphyrin and its derivative light emitting materials, carbazole and its derivative light emitting materials, pyrazine and its derivative light emitting materials, thiazole and its derivative light emitting materials, perylene and its derivative light emitting materials, silole and its derivative light emitting materials, tetraphenylethylene and its derivatives light emitting materials, polyphenylene ethylene and its derivative light emitting materials, polythiophene and its derivative light emitting materials, polyfluorene and its derivative light emitting materials, polyacetylene and its derivative light emitting materials, polycarbazole and its derivative light emitting materials, polypyridine and its derivative light emitting materials.

In an exemplary embodiment of the present disclosure, the thicknesses of the first emitting layer, the second emitting layer and the third emitting layer may be the same or different.

In an exemplary embodiment of the present disclosure, the difference between the thickness of the first emitting layer and the thickness of the second emitting layer may be 10 nm to 20 nm, and the difference between the thickness of the first emitting layer and the thickness of the third emitting layer may be 10 nm to 20 nm. For example, the difference between the thickness of the first emitting layer and the thickness of the second emitting layer may be 10 nm, 12 nm, 14 nm, 16 nm, 17 nm, 20 nm, and the difference between the thickness of the first emitting layer and the thickness of the third emitting layer may be 10 nm, 12 nm, 14 nm, 16 nm, 17 nm, 20 nm.

In an exemplary embodiment of the present disclosure, the thickness of the first emitting layer may be 10 nm to 20 nm less than the thickness of the second emitting layer, and the thickness of the first emitting layer may be 10 nm to 20 nm less than the thickness of the third emitting layer.

In an exemplary embodiment of the present disclosure, the thickness of the first emitting layer may be 15 nm to 25 nm, for example, may be 15 nm, 16 nm, 18 nm, 20 nm, 22 nm, 24 nm, 25 nm; the thickness of the second emitting layer may be 15 nm to 35 nm, for example, may be 15 nm, 16 nm, 18 nm, 20 nm, 22 nm, 24 nm, 25 nm; The thickness of the third emitting layer may be 15 nm to 35 nm, for example, may be 15 nm, 16 nm, 18 nm, 20 nm, 22 nm, 24 nm, 26 nm, 28 nm, 30 nm, 32 nm, 34 nm, 35 nm.

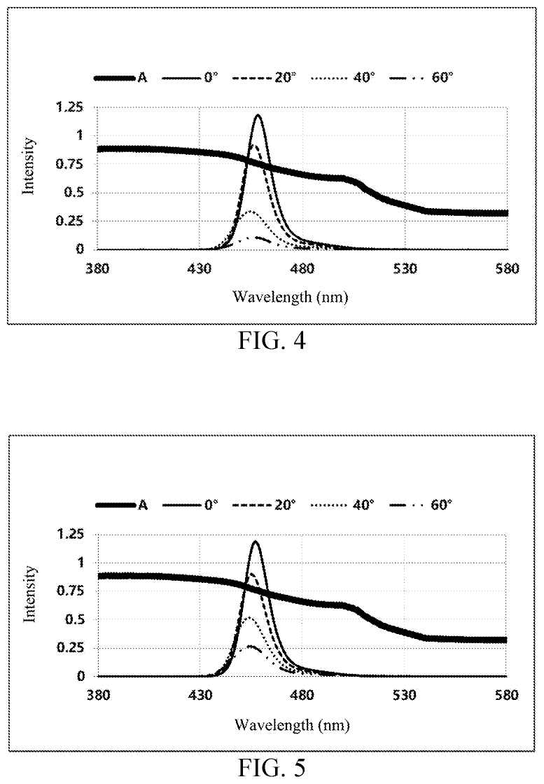

FIG. 4 is a spectrogram of an electroluminescence spectrum and an absorption spectrum of a first emitting layer of a light emitting substrate under different backlight viewing angles according to an exemplary embodiment of the present disclosure, FIG. 5 is a spectrogram of an electroluminescence spectrum and an absorption spectrum of a second emitting layer of the light emitting substrate shown in FIG. 4 under different backlight viewing angles, wherein A represents the absorption spectrum curve and other curves represent the electroluminescence spectrum curve; the material of the first emitting layer, the material of the second emitting layer and the material of the third emitting layer are selected from a group consisting of oxadiazole and its derivative light emitting materials, triazole and its derivative light emitting materials, rhodamine and its derivative light emitting materials, 1,8-naphthalimide and its derivative light emitting materials, pyrazoline and its derivative light emitting materials, triphenylamine and its derivative light emitting materials, porphyrin and its derivative light emitting materials, carbazole and its derivative light emitting materials, pyrazine and its derivative light emitting materials, thiazole and its derivative light emitting materials, perylene and its derivative light emitting materials, silole and its derivative light emitting materials, tetraphenylethylene and its derivative light emitting materials, polyphenylene ethylene and its derivative light emitting materials, polythiophene and its derivative light emitting materials, polyfluorene and its derivative light emitting materials, polyacetylene and its derivative light emitting materials, polycarbazole and its derivative light emitting materials, polypyridine and its derivative light emitting materials, the material of the first emitting layer is different from the material of the second emitting layer and the material of the first emitting layer is different from the material of the third emitting layer, the material of the second emitting layer and the material of the third emitting layer may be the same or different; the thickness of the first emitting layer is 15 nm to 25 nm, the thickness of the second emitting layer is 15 nm to 35 nm, and the thickness of the third emitting layer is 15 nm to 35 nm, the thicknesses of the first emitting layer, the second emitting layer and the third emitting layer may be the same or different.

As seen from FIG. 4 and FIG. 5, at a relatively small backlight viewing angle (for example, 0° to 20°), the electroluminescence spectra of the first emitting layer and the second emitting layer (or the third emitting layer) have little difference in intensity, however, at relatively large backlight viewing angles (for example, 40° to 60°), the intensity of the electroluminescence spectrum of the second emitting layer (or the third emitting layer) is significantly greater than the intensity of the electroluminescence spectrum of the first emitting layer. Therefore, the light emitted by the second emitting layer (or the third emitting layer) is more conducive to the absorption and utilization of quantum dots, and with the increase of the backlight angle, it can, to a certain extent, compensate for a situation that the quantum dots cannot absorb sufficient light energy at large viewing angle due to the rapid decrease of the intensity of the emitting layer. Therefore, when the light emitting substrate is used as the backlight of the QD-OLED device, the light output efficiency of the red sub-pixel area and the green sub-pixel area can be improved.

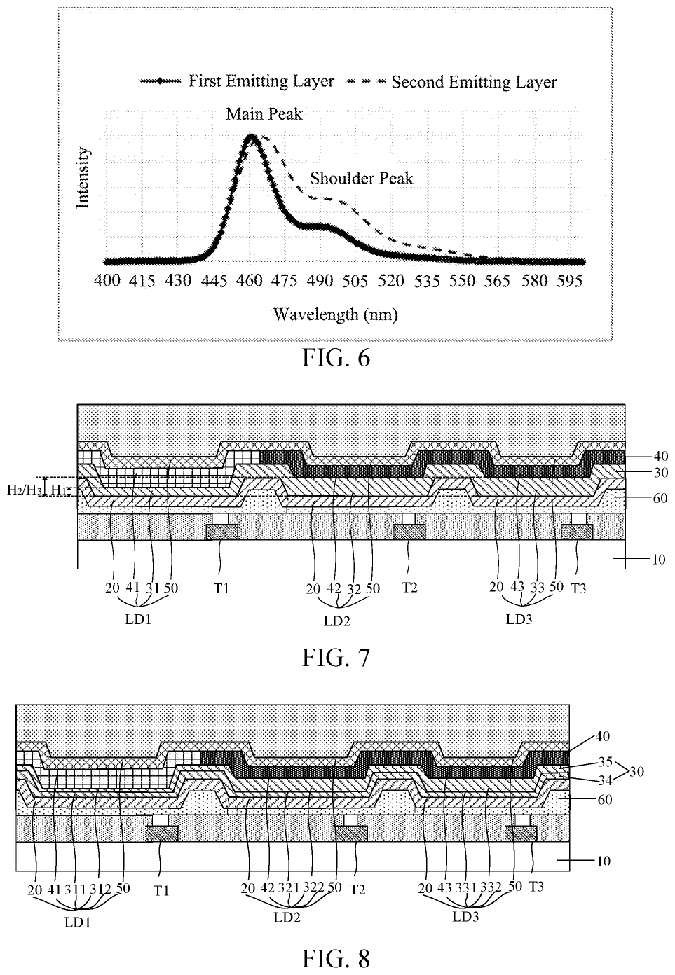

FIG. 6 is a spectrogram of a photoluminescence spectrum of the first emitting layer and the second emitting layer of the light emitting substrate according to an exemplary embodiment of the present disclosure, wherein the material of the first emitting layer, the material of the second emitting layer and the material of the third emitting layer are selected from a group consisting of oxadiazole and its derivative light emitting materials, triazole and its derivative light emitting materials, rhodamine and its derivative light emitting materials, 1, 8-naphthalimide and its derivative light emitting materials, pyrazoline and its derivative light emitting materials, triphenylamine and its derivative light emitting materials, porphyrin and its derivative light emitting materials, carbazole and its derivative light emitting materials, pyrazine and its derivative light emitting materials, thiazole and its derivative light emitting materials, perylene and its derivative light emitting materials, silole and its derivative light emitting materials, tetraphenylethylene and its derivative light emitting materials, polyphenylene ethylene and its derivative light emitting materials, polythiophene and its derivative light emitting materials, polyfluorene and its derivative light emitting materials, polyacetylene and its derivative light emitting materials, polycarbazole and its derivative light emitting materials, polypyridine and its derivative light emitting materials, the material of the first emitting layer is different from both the material of the second emitting layer and the material of the third emitting layer, the material of the second emitting layer and the material of the third emitting layer may be the same or different; the thickness of the first emitting layer is 15 nm to 25 nm, the thickness of the second emitting layer is 15 nm to 35 nm, and the thickness of the third emitting layer is 15 nm to 35 nm, the thicknesses of the first emitting layer, the second emitting layer and the third emitting layer may be the same or different.

As can be seen from FIG. 6, the photoluminescence spectrum of the first emitting layer includes a first main peak and a first shoulder peak, and the photoluminescence spectrum of the second emitting layer includes a second main peak and a second shoulder peak. The FWHM of the photoluminescence spectrum of the first emitting layer is about 20±2 nm, and the area of the first shoulder peak accounts for about 23%±4% of the area of the photoluminescence spectrum of the first emitting layer. The FWHM of the photoluminescence spectrum of the second emitting layer is about 28±2 nm, and the area of the second shoulder peak accounts for about 34±4% of the area of the photoluminescence spectrum of the second emitting layer. The peak wavelength of the first main peak is blue-shifted compared with the peak wavelength of the second main peak and these two may be equal in other exemplary embodiments. The peak wavelength of the first shoulder peak is about 490±5 nm, and the peak wavelength of the second shoulder peak is about 505±5 nm.

FIG. 7 is a schematic diagram of a structure of a light emitting substrate according to yet another embodiment of the present disclosure. In an exemplary embodiment of the present disclosure, as shown in FIG. 7, the light emitting functional layer may further include a hole transport layer 30 including a first hole transport layer 31 located in the first light emitting device LD1, a second hole transport layer 32 located in the second light emitting device LD2, and a third hole transport layer 33 located in the third light emitting device LD3;
the thickness H1 of the first hole transport layer 31 is less than the thickness H2 of the second hole transport layer 32, and the thickness H1 of the first hole transport layer 31 is less than the thickness H3 of the third hole transport layer 33.

In the description of the present disclosure, the thicknesses of the first hole transport layer, the second hole transport layer and the third hole transport layer refer to thicknesses of portions thereof located in the light emitting area.

When the thickness of the first hole transport layer is less than the thickness of the second hole transport layer and the thickness of the first hole transport layer is less than the thickness of the third hole transport layer, it is beneficial for improving the absorption and utilization of light by quantum dots in the red sub-pixel area and the green sub-pixel area, thereby improving the light conversion efficiency and emitted light value of the red sub-pixel area and the green sub-pixel area, improving the overall efficiency and color gamut level of the display device and reducing the power consumption of the display device.

In an exemplary embodiment of the present disclosure, the thickness of the first hole transport layer may be 10 nm to 30 nm less than the thickness of the second hole transport layer, for example, the thickness of the first hole transport layer may be 10 nm, 15 nm, 20 nm, 25 nm or 30 nm less than the thickness of the second hole transport layer;

the thickness of the first hole transport layer may be 10 nm to 30 nm less than the thickness of the third hole transport layer, for example, the thickness of the first hole transport layer may be 10 nm, 15 nm, 20 nm, 25 nm or 30 nm less than the thickness of the third hole transport layer.

In an exemplary embodiment of the present disclosure, the thickness of the second hole transport layer and the thickness of the third hole transport layer may be the same or different, for example, the thickness of the second hole transport layer may be 2 nm to 10 nm (e.g. 2 nm, 4 nm, 6 nm, 8 nm, 10 nm) less than the thickness of the third hole transport layer.

When the thickness of the first hole transport layer is 10 nm to 30 nm less than the thickness of the second hole transport layer, while the thickness of the first hole transport layer is 10 nm to 30 nm less than the thickness of the third hole transport layer, the absorption and excitation of light by quantum dots in the red sub-pixel area and the green sub-pixel area can be improved, the light emission efficiency of the red sub-pixel area and the green sub-pixel area can be improved, and its color gamut level can be ensured to be consistent with the current device structure.

FIG. 8 is a schematic diagram of a structure of a light emitting substrate according to yet another embodiment of the present disclosure. In an exemplary embodiment of the present disclosure, as shown in FIG. 8, in an exemplary embodiment of the present disclosure, the hole transport layer 30 may include a first sub-hole transport layer 34 and a second sub-hole transport layer 35 which are stacked, the first sub-hole transport layer 34 is disposed between the first electrode layer 20 and the light emitting functional layer, the second sub-hole transport layer 35 is disposed between the first sub-hole transport layer 34 and the light emitting functional layer. The first sub-hole transport layer 34 includes a first sub-layer of the first hole transport layer 311, a first sub-layer of the second hole transport layer 321 and a first sub-layer of the third hole transport layer 331 respectively located within the first light emitting device LD1, the second light emitting device LD2 and the third light emitting device LD3. The second sub-hole transport layer 35 includes a second sub-layer of the first hole transport layer 312, a second sub-layer of the second hole transport layer 322 and a second sub-layer of the third hole transport layer 332 respectively located within the first light emitting device LD1, the second light emitting device LD2 and the third light emitting device LD3. The first sub-layer of the first hole transport layer 311 and the second sub-layer of the first hole transport layer 312 constitute the first hole transport layer 31, the first sub-layer of the second hole transport layer 321 and the second sub-layer of the second hole transport layer 322 constitute the second hole transport layer 32, and the first sub-layer of the third hole transport layer 331 and the second sub-layer of the third hole transport layer 332 constitute the third hole transport layer 33.

In an exemplary embodiment of the present disclosure, the thicknesses of the first sub-layer of the first hole transport layer, the first sub-layer of the second hole transport layer and the first sub-layer of the third hole transport layer may all be the same/The thickness H12 of the second sub-layer of the first hole transport layer, the thickness H22 of the second sub-layer of the second hole transport layer, and the thickness H32 of the second sub-layer of the third hole transport layer can satisfy:
H12<H22, H12<H32, 0≤H12<50 nm, 0<H22≤50 nm, 0<H32≤50 nm.

In the exemplary embodiment of the present disclosure, the difference between the band gap of the second sub-hole transport layer and the first sub-hole transport layer may not exceed 0.25 eV, which is more conducive to realizing the transportation of carriers at the interface of the first sub-hole transport layer\ the second sub-hole transport layer\ the emitting layer, reducing the exciton loss to a certain extent, and optimizing the interface potential barrier.

In an exemplary embodiment of the present disclosure, a refractive index of the second sub-hole transport layer may be less than a refractive index of the first sub-hole transport layer and a refractive index of the emitting layer, which may be conducive to the reduction of the Fresnel loss at the interface of the first sub-hole transport layer and the second sub-hole transport layer, thus realizing a stronger light emission.

In an exemplary embodiment of the present disclosure, a material of the hole transport layer may include any one or more of a poly (p-phenylene vinylene) hole transport material, a polythiophene hole transport material, a polysilane hole transport material, a triphenylmethane hole transport material, a triarylamine hole transport material, a hydrazone hole transport material, a pyrazoline hole transport material, a chewazole hole transport material, a carbazole hole transport material and a butadiene hole transport material.

In an exemplary embodiment of the present disclosure, the materials of the first hole transport layer, the second hole transport layer, and the third hole transport layer may be the same or different.

In an exemplary embodiment of the present disclosure, the materials of the first sub-hole transport layer and the second sub-hole transport layer may be the same or different. When the materials of the first sub-hole transport layer and the second sub-hole transport layer are different, it is necessary to add an evaporation chamber to form two layers of hole transport layers, but the material selection of the hole transport layer can be increased, and the blue light emission enhancement as an RGQD backlight source can be further realized.

In an exemplary embodiment of the present disclosure, the materials of the first sub-layer of the first hole transport layer and the second sub-layer of the first hole transport layer may be the same or different, the materials of the first sub-layer of the second hole transport layer and the second sub-layer of the second hole transport layer may be the same or different, and the materials of the first sub-layer of the third hole transport layer and the second sub-layer of the third hole transport layer may be the same or different.

In an exemplary embodiment of the present disclosure, the light emitting functional layer may further include any one or more of a hole injection layer, an electron blocking layer, a hole blocking layer, an electron transport layer and an electron injection layer.

In an exemplary embodiment of the present disclosure, the first electrode layer may be an anode layer and the second electrode layer may be a cathode layer; alternatively, the first electrode layer may be a cathode layer and the second electrode layer may be an anode layer.

In an exemplary embodiment of the present disclosure, the first electrode layer is an anode layer, the second electrode layer is a cathode layer, the light emitting device may include: an anode layer, a hole injection layer, a hole transport layer, an electron blocking layer, an emitting layer, a hole blocking layer, an electron transport layer, an electron injection layer, a cathode layer and a pixel definition layer. The hole injection layer is disposed at a side of the anode layer, the hole transport layer is disposed at a side of the hole injection layer away from the anode layer, the electron blocking layer is disposed at a side of the hole transport layer away from the anode layer, the emitting layer is disposed at a side of the electron blocking layer away from the anode layer, the hole blocking layer is disposed at a side of the emitting layer away from the anode layer, the electron transport layer is disposed at a side of the hole blocking layer away from the anode layer, the electron injection layer is disposed at a side of the electron transport layer away from the anode layer, and the cathode layer is disposed at a side of the electron injection layer away from the anode layer.

In an exemplary embodiment of the present disclosure, the material of the anode layer may be a material with a high work function. For example, for top emission devices, the anode layer can adopt a composite structure of metal and transparent oxide, such as Ag/ITO (Indium Tin Oxide), Ag/IZO (Indium Zinc Oxide), Al/ITO, Al/IZO or ITO/Ag/ITO and the like, which can ensure good reflectivity.

In an exemplary embodiment of the present disclosure, the material of the hole injection layer may include transition metal oxides, for example, may include any one or more of molybdenum oxides, titanium oxides, vanadium oxides, rhenium oxides, ruthenium oxides, chromium oxides, zirconium oxides, hafnium oxides, tantalum oxides, silver oxides, tungsten oxides, manganese oxides.

In another exemplary embodiment, the material of the hole injection layer may include a p-type dopant of a strong electron absorption system and a hole transport material;
the p-type dopant includes any one or more of 2, 3, 6, 7, 1011-hexocyano-1, 4, 5, 8, 9, 12-hexazabenzophenanthrene, 2,3,5,6-tetrafluoro-7,7′,8,8′-tetracyano-p-benzoquinone, 1,2,3-tris[(cyano)(4-cyano-2,3,5,6-tetrafluorophenyl)methylene]cyclopropane;

The hole transport material may include any one or more of a arylamine hole transport material, a dimethylfluorene hole transport material, and a carbazole hole transport material; for example, the hole transport material may include and any one or more of: 4,4′-bis[N-(1-naphthyl)-N-phenylamino]biphenyl(NPB); N,N′-bis(3-methylphenyl)-N,N′-diphenyl-[1,1′-biphenyl]-4,4′-diamine(TPD); 4-phenyl-4′-(9-phenylfluoren-9-yl)triphenylamine(BAFLP); 4,4′-bis[N-(9,9-dimethylfluoren-2-yl)-N-phenylamino]biphenyl(DFLDPBi); 4,4′-bis(9-carbazolyl)biphenyl(CBP); 9-phenyl-3-[4-(10-phenyl-9-anthryl)phenyl]-9H-carbazole (PCzPA).

In an exemplary embodiment of the present disclosure, the hole injection layer may be formed by evaporation.

In an exemplary embodiment of the present disclosure, the hole transport layer may be formed by evaporation.

In an exemplary embodiment of the present disclosure, the material of the electron transport layer may include an aromatic heterocyclic electron transport material. For example, the electron transport material may include any one or more of benzimidazole and its derivatives may be included, imidazopyridine and its derivatives electron transport materials, benzimidazole phenanthrene derivatives electron transport materials, pyrimidine and its derivatives electron transport materials, triazine derivatives electron transport materials, pyridine and its derivatives electron transport materials, pyrazine and its derivatives electron transport materials, quinoxaline and its derivatives electron transport materials, diazole and its derivatives electron transport materials, quinoline and its derivatives electron transport materials, isoquinoline derivative electron transport materials, phenanthroline derivative electron transport materials, diazaphosphoropentadiene electron transport materials, phosphine oxide electron transport materials, aromatic ketone electron transport materials, lactam and borane electron transport materials.

For another example, the material of the electron transport layer may include any one or more of: 2-(4-biphenyl)-5-(4-tert-butylphenyl)-1,3,4-oxadiazole(PBD); 1,3-bis[5-(p-tert-butylphenyl)-1,3,4-oxadiazole-2-yl]benzene(OXD-7); 3-(4-tert-butylphenyl)-4-phenyl-5-(4-biphenyl)-1,2,4-triazole (TAZ); 3-(4-tert-butylphenyl)-4-(4-ethylphenyl)-5-(4-biphenyl)-1, 2,4-triazole(p-EtTAZ); red phenanthroline(BPhen); (BCP); 4,4′-bis(5-methylbenzoxazol-2-yl)stilbene (BzOs).

In an exemplary embodiment of the present disclosure, the material of the electron blocking layer may include any one or more of arylamine-based electron-blocking materials, dimethylfluorene-based electron-blocking materials, and carbazole-based electron-blocking materials; for example, the material of the electron blocking layer may include any one or more of: 4,4′-bis[N-(1-naphthyl)-N-phenylamino]biphenyl(NPB); N,N′-bis(3-methylphenyl)-N,N′-diphenyl-[1,1′-biphenyl]-4,4′-diamine(TPD); 4-phenyl-4′-(9-phenylfluoren-9-yl)triphenylamine(BAFLP); 4,4′-bis[N-(9,9-dimethylfluoren-2-yl)-N-phenylamino]biphenyl(DFLDPBi); 4,4′-bis(9-carbazolyl)biphenyl(CBP); 9-phenyl-3-[4-(10-phenyl-9-anthryl)phenyl]-9H-carbazole (PCzPA).

In an exemplary embodiment of the present disclosure, the electron blocking layer may be formed by evaporation.

In an exemplary embodiment of the present disclosure, the material of the hole blocking layer may include an aromatic heterocyclic hole barrier material, For example, hole blocking materials may include any one or more of benzimidazole and its derivative hole blocking materials, Imidazopyridine and its derivative hole blocking materials, benzimidazole phenanthridine derivative hole blocking materials, pyrimidine and its derivatives hole blocking materials, triazine derivative hole blocking materials, pyridine and its derivatives hole blocking materials, pyrazine and its derivatives hole blocking materials, quinoxaline and its derivatives hole blocking materials, diazole and its derivative hole blocking materials, quinoline and its derivative hole blocking materials, isoquinoline derivative hole blocking materials, phenanthroline derivative hole blocking materials, diazaphosphoropentadiene hole blocking materials, phosphine oxide hole blocking materials, aromatic ketone hole blocking materials, lactam, and borane hole blocking materials.

For another example, the material of the hole blocking layer may include any one or more of: 2-(4-biphenyl)-5-(4-tert-butylphenyl)-1,3,4-oxadiazole(PBD); 1,3-bis[5-(p-tert-butylphenyl)-1,3,4-oxadiazole-2-yl]benzene(OXD-7); 3-(4-tert-butylphenyl)-4-phenyl-5-(4-biphenyl)-1,2,4-triazole(TAZ); 3-(4-tert-butylphenyl)-4-(4-ethylphenyl)-5-(4-biphenyl)-1,2,4-triazole(p-EtTAZ); red phenanthroline (BPhen); (BCP); 4,4′-bis(5-methylbenzoxazol-2-yl)stilbene (BzOs).

In an exemplary embodiment of the present disclosure, the hole blocking layer may be formed by evaporation.

In exemplary embodiments of the present disclosure the material of the electron injection layer may include any one or more of an alkali metal electron injection material and a metal electron injection material. For example, the electron injection layer material may include any one or more of LiF, Yb, Mg, Ca.

In an exemplary embodiment of the present disclosure, the electron injection layer may be formed by evaporation.

In an exemplary embodiment of the present disclosure, the cathode may be formed by the metal with relatively low work function, such as Al, Ag, and Mg, or formed by an alloy containing a metal material with a low work function.

Embodiments of the present disclosure also provide a display panel, the display panel may have a plurality of repeated pixel units, at least one pixel unit includes a first sub-pixel, a second sub-pixel and a third sub-pixel displaying different colors, wherein the display panel includes the light emitting substrate provided in the above embodiment of the present disclosure, a thin film encapsulation layer, a color conversion layer, and a color filter layer; wherein,
the first light emitting device of the light emitting substrate is located in the first sub-pixel, the second light emitting device of the light emitting substrate is located in the second sub-pixel, and the third light emitting device of the light emitting substrate is located in the third sub-pixel;
the thin film encapsulation layer is disposed at a side of the light emitting substrate away from the first base substrate;
the color conversion layer is disposed at a side of the thin film encapsulation layer away from the first base substrate, the color conversion layer includes a transmission pattern, a first color conversion pattern and a second color conversion pattern, wherein the transmission pattern is located in the first sub-pixel, the first color conversion pattern is located in the second sub-pixel, and the second color conversion pattern is located in the third sub-pixel;
the color filter layer is positioned at a side of the color conversion layer away from the first base substrate and at least includes a first light shielding pattern, a first color filter pattern and a second color filter pattern, wherein the first light shielding pattern defines a plurality of light transmitting areas, wherein the light transmitting areas include a first light transmitting area corresponding to the first sub-pixel, a second light transmitting area corresponding to the second sub-pixel and a third light transmitting area corresponding to the third sub-pixel.

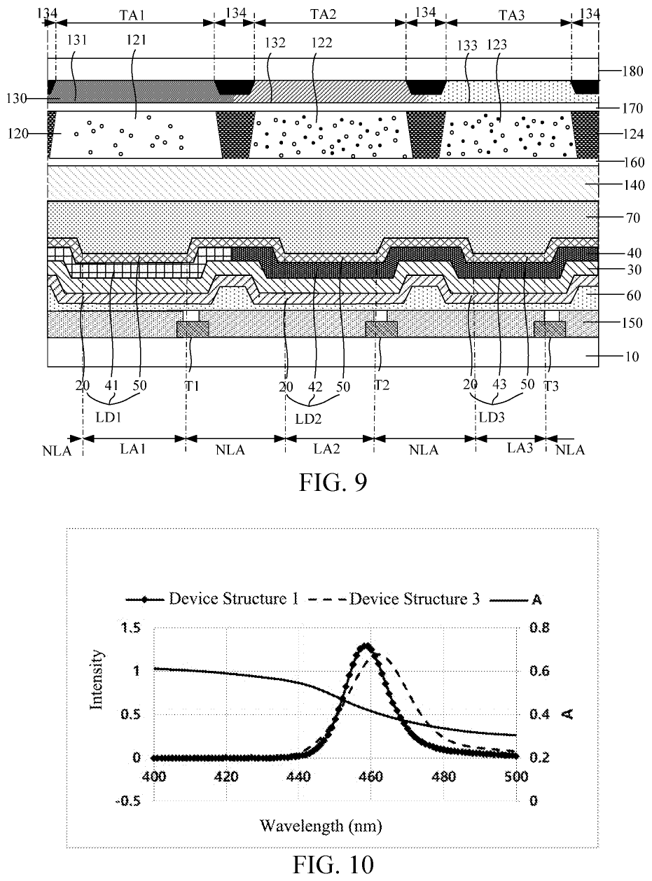

FIG. 9 is a schematic diagram of a structure of a display panel according to an exemplary embodiment of the present disclosure. As shown in FIG. 9, the display panel may have a plurality of repeated pixel units, at least one pixel unit includes a first sub-pixel, a second sub-pixel and a third sub-pixel displaying different colors, the display panel includes a first base substrate 10, a light emitting substrate as provided in the embodiments disclosed above, a thin film encapsulation layer 70, a color conversion layer 120, and a color filter layer 130; wherein,

The light emitting substrate includes a first base substrate 10, a plurality of light emitting devices disposed on the first base substrate 10. The light emitting devices include a first light emitting device LD1, a second light emitting device LD2 and a third light emitting device LD3, wherein the first light emitting device LD1 is located in the first sub-pixel, the second light emitting device LD2 is located in the second sub-pixel, and the third light emitting device LD3 is located in the third sub-pixel; the light emitting device includes a first electrode layer 20, a light emitting functional layer, a second electrode layer 50 and a pixel definition layer 60, the light emitting functional layer includes a hole transport layer 30 and an emitting layer 40. The first electrode layer 20 is disposed at a side of the first base substrate 10, the hole transport layer 30 is disposed at a side of the first electrode layer 20 away from the first base substrate 10, the emitting layer 40 is disposed at a side of the hole transport layer 30 away from the first base substrate 10, the second electrode layer 50 is disposed at a side of the emitting layer 40 away from the first base substrate 10, and the pixel definition layer 60 spaces apart the first light emitting device LD1, the second light emitting device LD2, and the third light emitting device LD3 of the light emitting devices; the emitting layer 40 includes a first emitting layer 41 located in the first light emitting device LD1, a second emitting layer 42 located in the second light emitting device LD2, and a third emitting layer 43 located in the third light emitting device LD3; wherein the material of the first emitting layer 41 is different from the material of the second emitting layer 42 and the material of the first emitting layer 41 is different from the material of the third emitting layer 43;
the thin film encapsulation layer 70 is disposed at a side of the light emitting substrate away from the first base substrate 10;
the color conversion layer 120 is disposed at a side of the thin film encapsulation layer 70 away from the first base substrate 10, the color conversion layer 120 includes a transmission pattern 121 located within the first sub-pixel, a first color conversion pattern 122 located within the second sub-pixel, a second color conversion pattern 123 located within the third sub-pixel, and a bank 124 spacing apart the transmission pattern 121, the first color conversion pattern 122, and the second color conversion pattern 123;
the color filter layer 130 is located at a side of the color conversion layer 120 away from the first base substrate 10 and at least includes a first light shielding pattern 131, a first color filter pattern 132 and a second color filter pattern 133 (i.e., a red color filter pattern and a green color filter pattern, the blue color filter pattern may be omitted, and the light shielding pattern may be made using a blue color filter pattern). The first light shielding pattern 131 defines a plurality of light transmitting areas including a first light transmitting area TA1 corresponding to the first sub-pixel, a second light transmitting area TA2 corresponding to the second sub-pixel, and a third light transmitting area TA3 corresponding to the third sub-pixel. The color filter layer 130 may also include a black matrix (BM) 134 spacing apart different sub-pixels.

In an exemplary embodiment of the present disclosure, the thin film encapsulation layer may include a first encapsulation layer, a second encapsulation layer and a third encapsulation layer that are sequentially stacked along a direction proximate to the first base substrate. The first encapsulation layer and the third encapsulation layer may be an inorganic encapsulation layer, and the second encapsulation layer may be an organic encapsulation layer. The material of the first encapsulation layer may be silicon nitride (SiNx) with a refractive index of 1.85 to 1.9 (e.g. may be 1.85 or 1.9) and a thickness of 0.6 μm; the second encapsulation layer may be an acrylic organic layer, for example, may be an acrylic organic layer with a refractive index of 1.45 to 1.5 and a thickness of 8 to 10 μm (e.g. may be 8.4 μm), and may be formed by an ink-jet printing (IJP) process; the material of the third encapsulation layer may be silicon oxynitride (SiON) with a refractive index of 1.70 to 1.8 (e.g., may be 1.70, 1.75 or 1.8) and a thickness of 0.6 μm to 1 μm (e.g., may be 1 μm).

In an exemplary embodiment of the present disclosure, as shown in FIG. 9, the display panel may also include a plurality of switch elements located on the first base substrate 10. In one repeat unit of the light emitting area, the switch elements include a first switch element T1, a second switch element T2, and a third switch element T3. For example, the first switch element T1 may be located in the first light emitting area LA1, the second switch element T2 may be located in the second light emitting area LA2, and the third switch element T3 may be located in the third light emitting area LA3. For another example, at least one of the first switch element T1, the second switch element T2 and the third switch element T3 may be located in the non-light emitting area NLA. At least one of the first switch element T1, the second switch element T2, and the third switch element T3 may be a thin film transistor including polysilicon or a thin film transistor including an oxide semiconductor. For example, when the switch element is a thin film transistor including an oxide semiconductor, it may be a thin film transistor structure with a top gate. The switch element may be connected with a signal line, and signal line includes, but not limited to, a gate line, a data line and a power supply line.

In an exemplary embodiment of the present disclosure, as shown in FIG. 9, the display panel may further include a filling layer 140 which may be disposed between the thin film encapsulation layer 70 and the color conversion layer 120. The filling layer can be an organic filling layer, which acts in flattening and bonding the back plate and the cover plate.

In an exemplary embodiment of the present disclosure, as shown in FIG. 9, the display panel may further include an insulation layer 150, which may be located on the first switch element T1, the second switch element T2 and the third switch element T3. The insulation layer 150 may have a planarized surface. The insulation layer 150 may be formed of an organic layer. For example, the insulation layer 150 may include an acrylic resin, an epoxy resin, an imide resin, or an ester resin. The insulation layer 150 may have through holes to expose the electrodes of the first switch element T1, the second switch element T2 and the third switch element T3 to facilitate electrical connection.

In an exemplary embodiment of the present disclosure, as shown in FIG. 9, the display panel may further include a first capping layer 160 between the filling layer 140 and the color conversion layer 120, and a second capping layer 170 between the color conversion layer 120 and the color filter layer 130. Quantum dots may react with water and/or oxygen to deteriorate, therefore, aiming at preventing or reducing the penetration of water and/or oxygen into the color conversion layer, the provision of a capping layer surrounding the color conversion layer can effectively prevent or reduce the occurrence of degradation of light emitting efficiency and defects that may be caused by the penetration of water and/or oxygen into the color conversion layer. The first capping layer 160 and the second capping layer 170 may be an inorganic material layer, for example, the material of the first capping layer 160 may be silicon oxynitride (SiON) with a refractive index of 1.8 and a thickness of 1 μm.

In an exemplary embodiment of the present disclosure, as shown in FIG. 9, the display panel may further include a second base substrate 180 located at a side of the color filter layer 130 away from the first base substrate 10.

In an exemplary embodiment of the present disclosure, as shown in FIG. 9, the display panel may further include a filling layer 140, an insulation layer 150, a first capping layer 160, a second capping layer 170 and a second base substrate 180.

Embodiments of the present disclosure further provides a display apparatus, including a plurality of display panels according to the embodiments of the present disclosure described above. The display apparatus may also include an Integrated Circuit (IC) for driving the display panel, and a power supply circuit.

The display apparatus may be any product or part with a display function, such as a mobile phone, a tablet computer, a television, a display, a laptop computer, a digital photo frame, a navigator, a vehicle-mounted display, a smart watch, and a smart bracelet.

The performance of a currently common quantum dot-organic light emitting diode and a display panel according to an exemplary embodiment of the present disclosure is compared below by means of graphs.

The currently common quantum dot-organic light emitting diode differs from the display panel according to exemplary embodiments of the present disclosure only in the material of the emitting layer (and the thickness of the hole transport layer):
the material of the emitting layer of a currently common quantum dot-organic light emitting diode is A, the thickness of the emitting layer is 20 nm, and the thickness of the hole transport layer is 100 nm, which is recorded as device structure 1;
the material of the emitting layer of a currently common quantum dot-organic light emitting diode is B, the thickness of the emitting layer is 20 nm, and the thickness of the hole transport layer is 100 nm, which is recorded as the device structure 1′;
an emitting layer of a display panel according to an exemplary embodiment of the present disclosure includes a first emitting layer located in a blue sub-pixel, a second emitting layer located in a red sub-pixel, a third emitting layer located in a green sub-pixel, the material of the first emitting layer is A, the thickness of the first emitting layer is 15 nm to 25 nm, the materials of the second emitting layer and the third emitting layer are B, and the thickness of the second emitting layer and the third emitting layer are both 15 nm to 35 nm, the thickness of hole transport layer is 100 nm, which is recorded as device structure 2;
an emitting layer of another display panel of an exemplary embodiment of the present disclosure includes a first emitting layer located in a blue sub-pixel, a second emitting layer located in a red sub-pixel, a third emitting layer located in a green sub-pixel, the material of the first emitting layer is A, the thickness of the first emitting layer is 15 nm to 25 nm, the materials of the second emitting layer and the third emitting layer are both B, and the thicknesses of the second emitting layer and the third emitting layer are both 15 nm to 35 nm; the hole transport layer includes a first hole transport layer located in a blue sub-pixel, a second hole transport layer located in a red sub-pixel, and a third hole transport layer located in a green sub-pixel, wherein the thickness of the first hole transport layer is 95 nm to 105 nm, and the thickness of the second hole transport layer and the third hole transport layer are both 100 nm to 115 nm, which is recorded as a device structure 3;
Material A and material B are both selected from oxadiazole and its derivative light emitting materials, triazole and its derivative light emitting materials, rhodamine and its derivative light emitting materials, 1, 8-naphthalimide and its derivative light emitting materials, pyrazoline and its derivative light emitting materials, triphenylamine and its derivatives light emitting materials, porphyrin and its derivative light emitting materials, carbazole and its derivative light emitting materials, pyrazine and its derivatives light emitting materials, thiazole and its derivative light emitting materials, perylene and its derivatives light emitting materials, silole and its derivative light emitting materials, tetraphenylethylene and its derivatives light emitting materials, polyphenylene ethylene and its derivatives light emitting materials, polythiophene and its derivatives light emitting materials, polyfluorene and its derivatives light emitting materials, polyacetylene and its derivatives light emitting materials, polycarbazole and its derivatives light emitting materials, polypyridine and its derivatives light emitting materials, however, material A is different from material B.

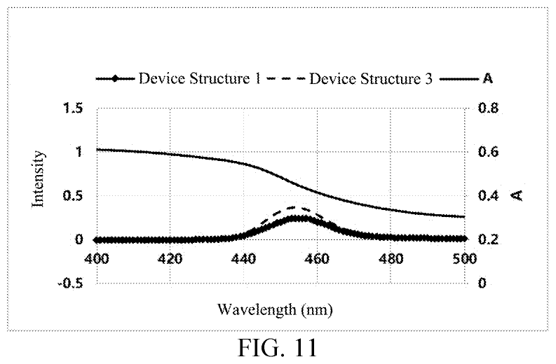

FIG. 10 is a spectrogram of electroluminescence spectrum and absorption spectrum of device structure 1 and device structure 3 at a backlight viewing angle of 0°, FIG. 11 is a spectrogram of electroluminescence spectrum and absorption spectrum of device structure 1 and device structure 3 at a backlight viewing angle of 50°, where A represents an absorption spectrum curve and other curves represent electroluminescence spectrum curves.

As can be seen from FIG. 10 and FIG. 11, compared with the device structure 1, in a relatively small viewing angle range (for example, 0° to 45°), taking 0° as an example, the intensity of the maximum peak of the electroluminescence spectrum of the device structure 3 is reduced and the spectrum is broadened, so the backlight of the device structure 3 and the backlight of the device structure 1 have relatively small difference in quantum dot absorption and conversion effects; in a relatively large viewing angle range (for example, 50° to 80°), taking 50° as an example, the intensity of the maximum peak of the device structure 3 is higher and the spectral width is larger in combination with the gain effect of the microcavity, so that the display panel according to an exemplary embodiment of the present disclosure is more conducive as a backlight to the absorption and utilization of quantum dots.

Table 1 shows the monochrome efficiency and white light efficiency of device structure 1 and device structure 2, including color coordinate, efficiency, W efficiency, color gamut, etc.

TABLE 1

| | B | | G | | R | | W | |
|---|---|---|---|---|---|---|---|---|
| Device Structure | Eff. | CIEy | Eff. | CIEx | Eff. | CIEx | Eff. | @BT2020 |
| Emitting Layer | 100% | 0.042 | 100% | 0.178 | 100% | 0.697 | 100% | 94.8% |
| (Device Structure 1) | | | | | | | | |
| Emitting Layer | 92.4% | 0.055 | 1135% | 0.179 | 108.8% | 0.697 | 101.7% | 91.5% |
| (Device Structure 1′) | | | | | | | | |
| First, Second and Third | 100% | 0.042 | 113.5% | 0.179 | 108.8% | 0.697 | 107.5% | 94.8% |
| Emitting Layers | | | | | | | | |
| (Device Structure 2) | | | | | | | | |

Table 2 shows the monochrome efficiency and white light efficiency of device structure 1 and device structure 3, including color coordinate, efficiency, W efficiency, color gamut, etc.

TABLE 2

| | B | | G | | R | | W | |
|---|---|---|---|---|---|---|---|---|
| Device Structure | Eff. | CIEy | Eff. | CIEx | Eff. | CIEx | Eff. | @BT2020 |
| Device Structure 1 | 100% | 0.042 | 100% | 0.175 | 100% | 0.694 | 100% | 94.2% |
| Device Structure 3 | 100% | 0.042 | 118.6% | 0.173 | 112.4% | 0.694 | 111.20% | 95.0% |

As can be seen from Table 1 and Table 2, the display panel according to an exemplary embodiment of the present disclosure can achieve the effects of improving the color gamut and light emitting efficiency of the device and reducing the power consumption of the device by designing emitting layers of different materials (and hole transport layers of different thicknesses). Compared with the device structure 1 or the device structure 1′, the device power consumption of the device structure 2 according to an exemplary embodiment of the present disclosure is reduced by about 8% to 10%; compared with the device structure 1, the device efficiency of the device structure 3 according to an exemplary embodiment of the present disclosure is improved by about 11%, and the color gamut @ BT2020 is at 95%, so the device power consumption is reduced by 11%.

Although the implementation modes disclosed in the present disclosure are as above, the described contents are only implementation modes used for convenience of understanding the present disclosure and are not intended to limit the present disclosure. Any person skilled in the art of the present disclosure may make any modification and change in forms and details of implementation without departing from the spirit and scope disclosed in the present disclosure. However, the scope of patent protection of the present disclosure is still subject to the scope defined in the appended claims.

1. A light emitting substrate, comprising:
a first base substrate;
a plurality of light emitting devices on the first base substrate, wherein the light emitting devices comprise a first light emitting device, a second light emitting device and a third light emitting device, each of the light emitting devices comprises a first electrode layer, a light emitting functional layer and a second electrode layer which are stacked, the light emitting functional layer comprises an emitting layer, the emitting layer comprises a first emitting layer in the first light emitting device, a second emitting layer in the second light emitting device and a third emitting layer in the third light emitting device;
wherein a material of the first emitting layer is different from a material of the second emitting layer, and a material of the first emitting layer is different from a material of the third emitting layer.

2. The light emitting substrate according to claim 1, wherein
a photoluminescence spectrum of the first emitting layer comprises a first main peak and a first shoulder peak,
a photoluminescence spectrum of the second emitting layer comprises a second main peak and a second shoulder peak, and
a photoluminescence spectrum of the third emitting layer comprises a third main peak and a third shoulder peak.

3. The light emitting substrate according to claim 2, wherein
a Full Width At Half-Maximum (FWHM) of the photoluminescence spectrum of the first emitting layer is narrower than a FWHM of the photoluminescence spectrum of the second emitting layer, and
a FWHM of the photoluminescence spectrum of the first emitting layer is narrower than a FWHM of the photoluminescence spectrum of the third emitting layer.

4. The light emitting substrate according to claim 3, wherein
a ratio of the FWHM of the photoluminescence spectrum of the first emitting layer to the FWHM of the photoluminescence spectrum of the second emitting layer is 0.6:1 to 0.85:1, and
a ratio of the FWHM of the photoluminescence spectrum of the first emitting layer to the FWHM of the photoluminescence spectrum of the third emitting layer is 0.6:1 to 0.85:1.

5. The light emitting substrate according to claim 4, wherein
the FWHM of a photoluminescence spectrum of the first emitting layer is 20±2 nm, the FWHM of the photoluminescence spectrum of the second emitting layer is 28±2 nm, and
the FWHM of the photoluminescence spectrum of the third emitting layer is 28±2 nm.

6. The light emitting substrate according to claim 2, wherein
a ratio of a proportion of an area of the first shoulder peak in the photoluminescence spectrum of the first emitting layer to a proportion of an area of the second shoulder peak in the photoluminescence spectrum of the second emitting layer is 0.5:1 to 0.9:1, and
a ratio of the proportion of the area of the first shoulder peak in the photoluminescence spectrum of the first emitting layer to a proportion of an area of the third shoulder peak in the photoluminescence spectrum of the third emitting layer is 0.5:1 to 0.9:1.

7. The light emitting substrate according to claim 6, wherein
the area of the first shoulder peak accounts for 23%±4% of the area of the photoluminescence spectrum of the first emitting layer,
the area of the second shoulder peak accounts for 34%±4% of the area of the photoluminescence spectrum of the second emitting layer, and
the area of the third shoulder peak accounts for 34%±4% of the area of the photoluminescence spectrum of the third emitting layer.

8. The light emitting substrate according to claim 2, wherein
a difference between a peak wavelength of the first shoulder peak and a peak wavelength of the second shoulder peak is 5 nm to 25 nm, and
a difference between the peak wavelength of the first shoulder peak and a peak wavelength of the third shoulder peak is 5 nm to 25 nm.

9. The light emitting substrate according to claim 8, wherein
the peak wavelength of the first shoulder peak is 490±5 nm, the peak wavelength of the second shoulder peak is 505±5 nm, and the peak wavelength of the third shoulder peak is 505±5 nm.

10. The light emitting substrate according to claim 1, wherein
the material of the first emitting layer, the material of the second emitting layer, and the material of the third emitting layer may each independently comprises any one or more of oxadiazole and its derivative light emitting materials, triazole and its derivative light emitting materials, rhodamine and its derivative light emitting materials, 1,8-naphthalimide and its derivative light emitting materials, pyrazoline and its derivative light emitting materials, triphenylamine and its derivative light emitting materials, porphyrin and its derivative light emitting materials, carbazole and its derivative light emitting materials, pyrazine and its derivative light emitting materials, thiazole and its derivative light emitting materials, perylene and its derivative light emitting materials, silole and its derivative light emitting materials, tetraphenylethylene and its derivatives light emitting materials, polyphenylene ethylene and its derivative light emitting materials, polythiophene and its derivative light emitting materials, polyfluorene and its derivative light emitting materials, polyacetylene and its derivative light emitting materials, polycarbazole and its derivative light emitting materials, polypyridine and its derivative light emitting materials.

11. The light emitting substrate according to claim 1, wherein a difference between a thickness of the first emitting layer and a thickness of the second emitting layer is 10 nm to 20 nm, and a difference between the thickness of the first emitting layer and a thickness of the third emitting layer is 10 nm to 20 nm.

12. The light emitting substrate according to claim 11, wherein the thickness of the first emitting layer is 15 nm to 25 nm, the thickness of the second emitting layer is 15 nm to 35 nm, and the thickness of the third emitting layer is 15 nm to 35 nm.

13. The light emitting substrate according to claim 1, wherein, the light emitting functional layer further comprises a hole transport layer, and the hole transport layer comprises a first hole transport layer located in the first light emitting device, a second hole transport layer located in the second light emitting device and a third hole transport layer located in the third light emitting device;
wherein a thickness of the first hole transport layer is less than a thickness of the second hole transport layer, and the thickness of the first hole transport layer is less than a thickness of the third hole transport layer.

14. The light emitting substrate according to claim 13, wherein the thickness of the first hole transport layer is 10 nm to 30 nm less than the thickness of the second hole transport layer, and the thickness of the first hole transport layer is 10 nm to 30 nm less than the thickness of the third hole transport layer.

15. The light emitting substrate according to claim 13, wherein
the hole transport layer comprises a first sub-hole transport layer and a second sub-hole transport layer which are stacked,
the first sub-hole transport layer is disposed between the first electrode layer and the light emitting functional layer,
the second sub-hole transport layer is disposed between the first sub-hole transport layer and the light emitting functional layer,
the first sub-hole transport layer comprises a first sub-layer of the first hole transport layer, a first sub-layer of the second hole transport layer and a first sub-layer of the third hole transport layer respectively located in the first light emitting device, the second light emitting device and the third light emitting device,
the second sub-hole transport layer comprises a second sub-layer of the first hole transport layer, a second sub-layer of the second hole transport layer and a second sub-layer of the third hole transport layer respectively located in the first light emitting device, the second light emitting device and the third light emitting device,
the first sub-layer of the first hole transport layer and a the second sub-layer of the first hole transport layer constitute the first hole transport layer,
the first sub-layer of the second hole transport layer and the second sub-layer of the second hole transport layer constitute the second hole transport layer, and
the first sub-layer of the third hole transport layer and the second sub-layer of the third hole transport layer constitute the third hole transport layer.

16. The light emitting substrate according to claim 15, wherein
thicknesses of the first sub-layer of the first hole transport layer, the first sub-layer of the second hole transport layer and the first sub-layer of the third hole transport layer are all the same, and a thickness H12 of the second sub-layer of the first hole transport layer,
thickness H22 of the second sub-layer of the second hole transport layer, and a thickness H32 of the second sub-layer of the third hole transport layer satisfy:
H12<H22, H12<H32, 0≤H12<50 nm, 0<H22≤50 nm, 0<H32≤50 nm.

17. The light emitting substrate according to claim 15, wherein a difference between a band gap of the second sub-hole transport layer and a band gap of the first sub-hole transport layer does not exceed 0.25 eV; and/or
a refractive index of the second sub-hole transport layer is less than a refractive index of the first sub-hole transport layer and a refractive index of the emitting layer.

18. (canceled)

19. The light emitting substrate according to claim 13, wherein
a material of the hole transport layer comprises any one or more of a poly (p-phenylene vinylene) hole transport material, a polythiophene hole transport material, a polysilane hole transport material, a triphenylmethane hole transport material, a triarylamine hole transport material, a hydrazone hole transport material, a pyrazoline hole transport material, a chewazole hole transport material, a carbazole hole transport material and a butadiene hole transport material.

20. A display panel, has a plurality of repeated pixel units, and at least one pixel unit comprises a first sub-pixel, a second sub-pixel, and a third sub-pixel displaying different colors, wherein the display panel comprises the light emitting substrate according to claim 1, a thin film encapsulation layer, a color conversion layer and a color filter layer; wherein,
the first light emitting device of the light emitting substrate is located in the first sub-pixel, the second light emitting device of the light emitting substrate is located in the second sub-pixel, and the third light emitting device of the light emitting substrate is located in the third sub-pixel;
the thin film encapsulation layer is disposed at a side of the light emitting substrate away from the first base substrate;
the color conversion layer is disposed at a side of the thin film encapsulation layer away from the first base substrate, the color conversion layer comprises a transmission pattern, a first color conversion pattern and a second color conversion pattern, the transmission pattern is located in the first sub-pixel, the first color conversion pattern is located in the second sub-pixel, and the second color conversion pattern is located in the third sub-pixel;
the color filter layer is positioned at a side of the color conversion layer away from the first base substrate and at least comprises a first light shielding pattern, a first color filter pattern and a second color filter pattern, the first light shielding pattern defines a plurality of light transmitting areas, and the light transmitting areas comprise a first light transmitting area corresponding to the first sub-pixel, a second light transmitting area corresponding to the second sub-pixel and a third light transmitting area corresponding to the third sub-pixel.

21. A display apparatus, comprising the display panel according to claim 20, a drive integrated circuit, and a power supply circuit.
